(19) United States
(12) Patent Application Publication
(10) Pub. No.: US 2012/0162869 A1
(43) Pub. Date: Jun. 28, 2012

(54) CABLE POSITIONING MECHANISM AND ELECTRONIC DEVICE USING THE SAME

(75) Inventors: MIN-LI LI, Shenzhen City (CN); NA WANG, Shenzhen City (CN); YONG-JUN YU, Shenzhen City (CN); HE-LI WANG, Shenzhen City (CN)

(73) Assignees: HON HAI PRECISION INDUSTRYCO., LTD., Tu-Cheng (TW); HONG FU JIN PRECISION INDUSTRY(ShenZhen) CO., LTD., Shenzhen City (CN)

(21) Appl. No.: 13/167,907

(22) Filed: Jun. 24, 2011

(30) Foreign Application Priority Data
Dec. 28, 2010 (CN) 201010608990.9

(51) Int. Cl. H05K 5/00; F16L 3/16

(52) U.S. Cl. 361/679.01; 248/74.1

(57) ABSTRACT

A cable positioning mechanism for fastening a cable, includes a main body and at least three positioning members arranged on the main body. The at least three positioning members cooperatively fasten the cable to the main body by every two of the at least three positioning members clamping the cable therebetween. An electronic device using the cable positioning mechanism is also provided.

### BACKGROUND

1. Technical Field

The present disclosure relates to a cable positioning mechanism and an electronic device using the cable positioning mechanism.

2. Description of Related Art

An electronic device always includes a plurality of cables for electrically connecting different electronic components. However, most of the time, the cables in the electronic device are arranged disorderly and unsystematic.

Therefore, there is room for improvement in the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the three views.

FIG. 1 is a perspective view of an electronic device in accordance with an exemplary embodiment; the electronic device includes a cable positioning mechanism.

FIG. 2 is a perspective view of the cable positioning mechanism of the electronic device of FIG. 1.

FIG. 3 is a perspective view showing the cable positioning mechanism of FIG. 2 fastening a cable.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

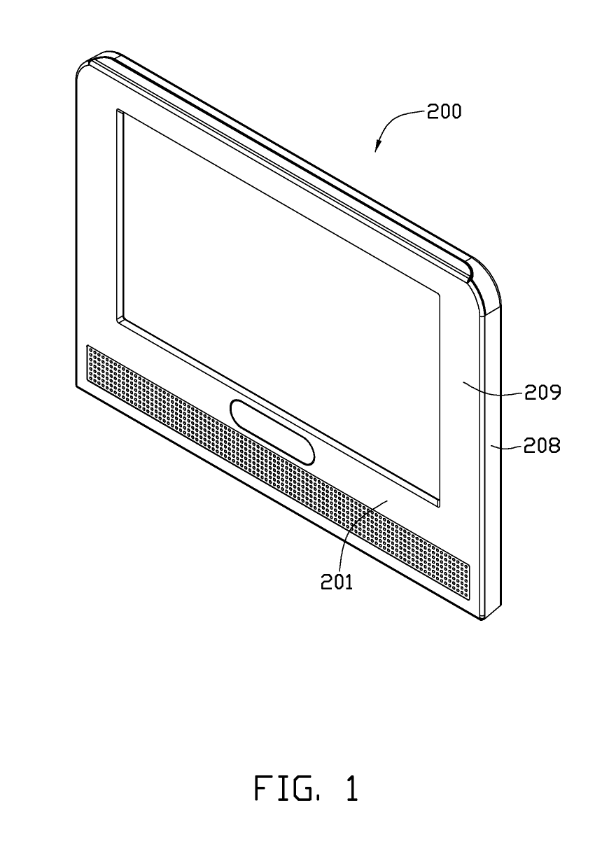

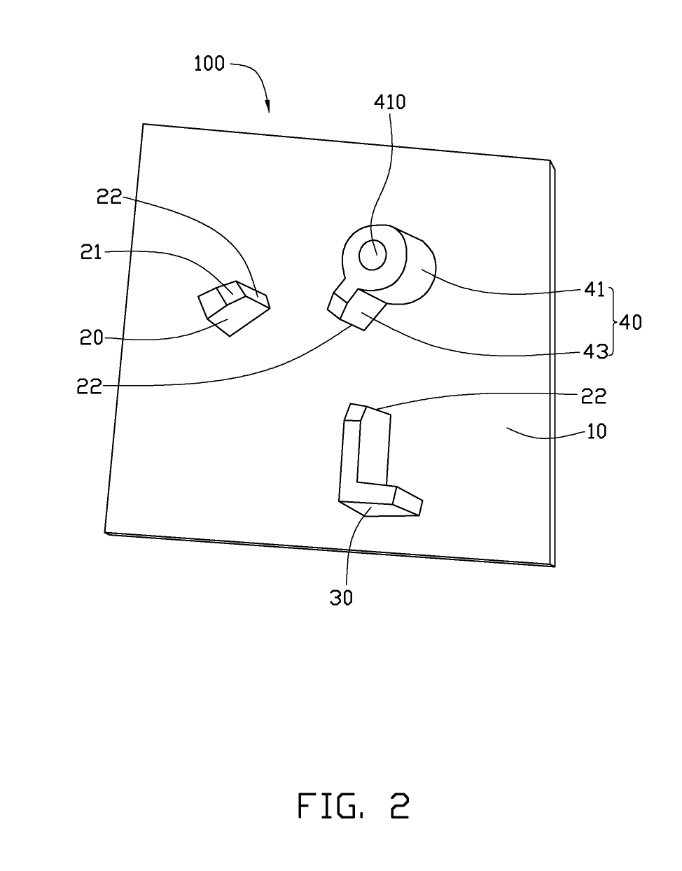

Referring to FIGS. 1-3, an electronic device 200 in accordance with an embodiment is shown. The electronic device 200 includes a housing 201, a cable positioning mechanism 100 accommodated in the housing 201, and a cable 203 received in the housing 201.

The housing 201 includes a front cover 208 and a rear cover 209 engaging with the front cover 208. The front cover 208 and the rear cover 209 cooperatively define a receiving space (not labeled) for receiving the cable positioning mechanism 100, the cable 203 and other components of the electronic device 200, such as, circuit board. The cable 203 can be wires electrically connecting components of the electronic device 100.

The cable positioning mechanism 100 includes a main body 10, and three positioning members 20, 30, 40 (hereinafter, a first positioning member 20, a second positioning member 30, and a third positioning member 40) arranged on the main body 10. In the embodiment, the main body 10 is the rear cover 209 of the housing 201. The first positioning member 20 has an irregular shape. The second positioning member 30 is substantially L-shaped. The third positioning 40 includes a substantially cylindrical fixing portion 41 and a positioning portion 43 extending from the fixing portion 41. The fixing portion 41 defines a fixing hole 410 for receiving bolts (not shown), whereby the third positioning member 40 is secured to the main body 10. The first, second, and third positioning members 20, 30, 40 are arranged on the main body 10 in a triangle. Each positioning members includes a positioning point 22. The positioning points 22 resist against the cable 203 when the cable 203 is fasten to the cable positioning mechanism 100. The positioning points 22 are not aligned in a straight line. The distance between the positioning points of the first and third positioning members 20, 40, and the distance between the positioning points of the second and third positioning members 30, 40 are slightly less than the diameter of the cable 203. A side of one of positioning members adjacent to another positioning member defines a sloped guiding portion 21. The guiding portion 21 is configured to guide the cable 203 to be clamped between the first, second, and third positioning members 20, 30, 40, such that the cable 203 can be fastened to the cable positioning mechanism 100 easily. In other embodiment, the shape of the first, second, third positioning members 20, 30, 40 may be changeable. The number of the positioning members may be more than three.

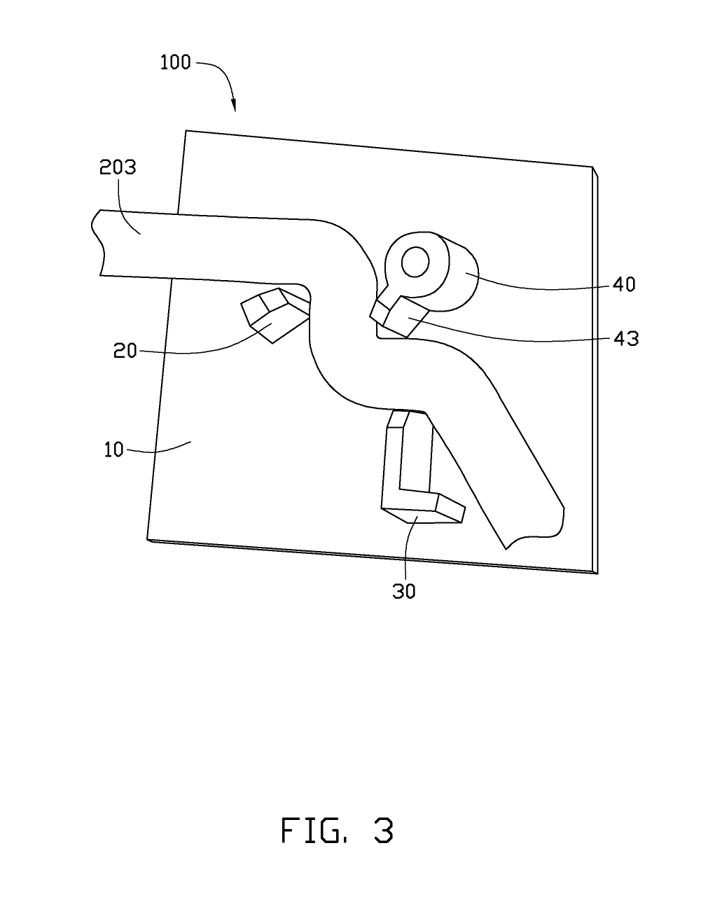

Referring to FIG. 3, in use, the first step is to clamp the cable 203 between the first and third positioning members 20, 40. Then, the cable 203 rounds the third position member 40, and is clamped between the second and third positioning members 30, 40. As the first, second, third members 20, 30, 40 are arranged on the main body 10 in a triangle. In addition, the distance between the positioning points of the first and third positioning members 20, 40, and the distance between the positioning points of the second and third positioning members 30, 40 are slightly less than the diameter of the cable 203, thus, the cable 203 is steadily fastened by the cable positioning mechanism 100.

It is to be understood, even though information and advantages of the present embodiments have been set forth in the foregoing description, together with details of the structures and functions of the present embodiments, the disclosure is illustrative only; and that changes may be made in detail, especially in matters of shape, size, and arrangement of parts within the principles of the present embodiments to the full extent indicated by the broad general meaning of the terms in which the appended claims are expressed.

What is claimed is:

1. A cable positioning mechanism for fastening a cable, comprising:
a main body; and
at least three positioning members arranged on the main body for cooperatively fastening the cable to the main body;
wherein every two of the at least three positioning members clamp the cable therebetween.

2. The cable positioning mechanism of claim 1, wherein each positioning member comprising a positioning point, the positioning point resists against the cable when the cable is fasten to the positioning mechanism.

3. The cable positioning mechanism of claim 2, wherein the positioning points are not aligned in a straight line.

4. The cable positioning mechanism of claim 3, wherein the distance between at least two of the positioning points are slightly less than the diameter of the cable.

5. The cable positioning mechanism of claim 1, wherein the cable positioning mechanism comprises three positioning members arranged on the main body in a triangle.

6. The cable positioning mechanism of claim 1, wherein an end of each positioning members defines a guiding portion adapted to guide the cable to be clamped between every two of the at least three positioning members.

7. An electronic device, comprising:
a housing; and
at least one cable positioning mechanism accommodated in the housing, each cable positioning mechanism comprising at least three positioning members, and the at least three positioning members being configured for cooperatively fastening the cable to the housing;
wherein every two of the at least three positioning members clamp the cable therebetween.

8. The electronic device of claim 6, wherein each positioning member comprising a positioning point, and the positioning point resists against the cable when the cable is fasten to the positioning mechanism.

9. The electronic device of claim 8, wherein the positioning points are not aligned in a straight line.

10. The electronic device of claim 9, wherein the distance between at least two of the positioning points are slightly less than the diameter of the cable.

11. The electronic device of claim 7, wherein the cable positioning mechanism comprises three positioning members, the three positioning member are arranged in a triangle.

12. The electronic device of claim 7, wherein an end of each positioning members defines a guiding portion adapted to guide the cable to be clamped between two of the at least three positioning members.

13. The electronic device of claim 7, wherein the at least three positioning members are mounted to a rear cover of the housing.
